(19) United States
(12) Patent Application Publication
(10) Pub. No.: US 2025/0054786 A1
(43) Pub. Date: Feb. 13, 2025

(54) DIE BONDING TOOL WITH MOVABLE COMPONENT FOR IMPROVED DIE PROTRUSION CONTROL AND METHODS FOR USING THE SAME

(71) Applicant: Taiwan Semiconductor Manufacturing Company Limited, Hsinchu (TW)

(72) Inventors: Chih-Yuan Chiu, Zhudong Township (TW); Chi-Chun Peng, Hsinchu (TW); Yu-Hong Du, Hsinchu (TW); Hui-Ting Lin, Tainan City (TW); Jen-Hao Liu, Zhunan Township (TW); Amram Eitan, Hsinchu (TW)

(21) Appl. No.: 18/230,719

(22) Filed: Aug. 7, 2023

(51) Int. Cl. H01L 21/67; H01L 21/52; H01L 21/683

(52) U.S. Cl. CPC H01L 21/67144; H01L 21/52; H01L 21/6838

(57) ABSTRACT

A die bonding tool includes a bond head having a moveable component. The moveable component may be moveable between an extended position in which a lower surface of the moveable component protrudes below a lower surface of the bond head and a retracted position in which the lower surface of the moveable component does not protrude below the lower surface of the bond head. The moveable component may be used to control a shape of a semiconductor die secured to the lower surface of the bond head during a process of bonding the semiconductor die to a substrate. Accordingly, void areas and other bonding defects may be avoided and the bond formed between the semiconductor die and the target substrate may be improved.

### BACKGROUND

The semiconductor industry has grown due to continuous improvements in integration density of various electronic components (e.g., transistors, diodes, resistors, capacitors, etc.). For the most part, these improvements in integration density have come from successive reductions in minimum feature size, which allows more components to be integrated into a given area.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or integrated SoC devices. Some of these three-dimensional devices (e.g., 3DIC, SoC, integrated SoC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a die bonding tool according to various embodiments of the present disclosure.

FIG. 2A is a vertical cross-section view of a die bonding tool illustrating a bond head of the die bonding tool aligned over the upper surface of a semiconductor integrated circuit (IC) die according to an embodiment of the present disclosure.

FIG. 2B is a vertical cross-section view of the die bonding tool illustrating the bond head contacting the upper surface of the semiconductor IC die according to an embodiment of the present disclosure.

FIG. 2C is a vertical cross-section view of the die bonding tool illustrating the semiconductor IC die secured to the bond head according to an embodiment of the present disclosure.

FIG. 2D is a vertical cross-section view of the die bonding tool illustrating the bond head and the semiconductor IC die attached thereto aligned over the upper surface of a target substrate according to an embodiment of the present disclosure.

FIG. 2E is a vertical cross-section view of the die bonding tool illustrating the bond head and the semiconductor IC die attached thereto moved vertically downward towards the upper surface of the target substrate according to an embodiment of the present disclosure.

FIG. 2F is a bottom-up view of the semiconductor IC die schematically illustrating the bonding wave produced during a process of bonding the lower surface of the semiconductor IC die to the upper surface of the target substrate according to an embodiment of the present disclosure.

FIG. 2G is a vertical cross-section view of the die bonding tool illustrating the bond head and the semiconductor IC die attached thereto moved further towards the upper surface of the target substrate according to an embodiment of the present disclosure.

FIG. 2H is a bottom-up view of the semiconductor IC die schematically illustrating the propagation of the bonding wave during a subsequent stage of the bonding process according to an embodiment of the present disclosure.

FIG. 2I is a vertical cross-section view of the die bonding tool illustrating the bond head moved further towards the upper surface of the target substrate to bring the entire lower surface of the semiconductor IC die into contact with the upper surface of the target substrate according to an embodiment of the present disclosure.

FIG. 2J is a bottom-up view of the semiconductor IC die schematically illustrating the propagation of the bonding wave during a subsequent stage of the bonding process according to various embodiments of the present disclosure.

FIG. 2K is a vertical cross-section view of the die bonding tool following a bonding process that bonds the semiconductor IC die to the target substrate according to an embodiment of the present disclosure.

FIG. 3A is a vertical cross-section view of a die bonding tool including a moveable component protruding below the lower surface of the nozzle plate of the bond head according to another embodiment of the present disclosure.

FIG. 3B is a vertical cross-section view of the die bonding tool of FIG. 3A illustrating the moveable component in a retracted position according to an embodiment of the present disclosure.

FIG. 4 is a flowchart illustrating a method of bonding a semiconductor die to a target substrate according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In various embodiments, a die bonding tool may be used to bond a semiconductor integrated circuit (IC) die (which may also be referred to as a “chip”) to a target substrate, such as a semiconductor wafer. The die bonding tool may include a bond head that is configured to temporarily adhere a semiconductor IC die to the bond head, such as via a vacuum suction force. The die bonding tool may align the semiconductor IC die over a bonding region of the target substrate and may apply a compressive force to the semiconductor IC die to bond the semiconductor IC die to the bonding region of the target substrate.

The bond head of the die bonding tool may temporarily secure the semiconductor IC die to a lower surface of the bond head using a suction force applied through one or more openings or ports in the lower surface of the bond head. Once the semiconductor IC die is properly aligned over and brought into contact with the bonding region of the target substrate, the suction force on the semiconductor IC die may be released thereby releasing the semiconductor IC die from the bond head of the die bonding tool. In many cases, mechanical deformations in the semiconductor IC die, such as a natural warping of the die, may result in air pockets or bubbles becoming trapped between the lower surface of the semiconductor IC die and the upper surface of the target substrate during the bonding process. Accordingly, following the bonding process, there may be void areas between the interfacing surfaces of the semiconductor IC die and the target substrate, which may result in poor or defective bonding and reduced device yields.

In order to improve the bonding between a semiconductor IC die and a target substrate, various embodiments of the present disclosure are directed to a die bonding tool that includes a bond head having a moveable component that is moveable within an internal chamber of the bond head. The moveable component may be moveable between a first (i.e., extended) position in which a lower surface of the moveable component protrudes below the lower surface of the bond head and a second (i.e., retracted) position in which the lower surface of the moveable component does not protrude below the lower surface of the bond head. In some embodiments, a fluid source coupled to the internal chamber of the bond head may be used to hydraulically control the position of the movable component with respect to the lower surface of the bond head. In other embodiments, a mechanical drive system may control the position of the moveable component with respect to the lower surface of the bond head.

In various embodiments, during a process of bonding a semiconductor IC die to a target substrate, the moveable component may be maintained in an extended position with the lower surface of the moveable component protruding below the lower surface of the bond head to impart a concave shape to the semiconductor IC die. The concave shape of the semiconductor IC die may be maintained as the bond head moves the semiconductor IC die into initial contact with the target substrate. As the die bonding tool continues to place the semiconductor IC die onto the target substrate, the moveable component may be retracted into the internal chamber to gradually “flatten out” the concave shape of the semiconductor IC die as the contact area between the semiconductor IC die and the target substrate is increased. By controlling the shape of the semiconductor IC die during the placement of the semiconductor IC die onto the target substrate, the formation of air pockets or bubbles may be mitigated, and a bonding wave between the semiconductor IC die and target substrate may propagate radially outwards from a central region of the semiconductor IC die to the periphery of the semiconductor IC die in a smooth and controlled manner. Accordingly, void areas and other bonding defects may be mitigated and the quality and reliability of the bond formed between the semiconductor IC die and the target substrate may be improved.

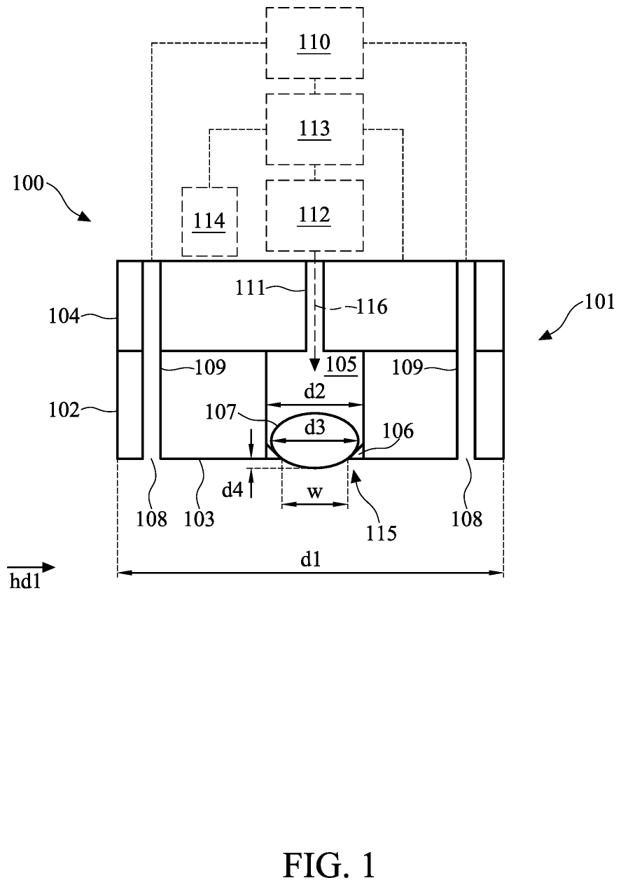

FIG. 1 is a vertical cross-sectional view of a die bonding tool 100 according to various embodiments of the present disclosure. The die bonding tool 100 may include a bond head 101 and an actuator system 114 configured to move the bond head 101. The bond head 101 may include a nozzle plate 102 having a substantially flat lower surface 103. The nozzle plate 102 of the bond head 101 may also include one or more openings 108 (i.e., ports) in the lower surface 103 of the nozzle plate 102. Fluid conduits 109 may couple each of the ports 108 of the nozzle plate 102 to a vacuum source 110. The vacuum source 110 may selectively apply a negative pressure within the fluid conduits 109 such that a vacuum or suction force may be generated at each of the ports 108 in the nozzle plate 102. Thus, the ports 108 may also be referred to as vacuum ports 108. The suction force at the ports 108 may be sufficient to secure a semiconductor IC die against the lower surface 103 of the nozzle plate 102.

In some embodiments, the die bonding tool 100 may also include a heat source 104 that may be used to apply heat to the semiconductor IC die and the target substrate during a die bonding process. In the embodiment of FIG. 1, the heat source 104 may include one or more heating elements, such as resistive heating elements, located within the bond head 101 that may be configured to heat the semiconductor IC die via thermal conduction through the nozzle plate 102.

The die bonding tool 100 may include a system controller 113, which may be central processing unit (CPU), that may be operatively coupled to the actuator system 114. The system controller 113 may be configured to send control signals to the actuator system 114 to cause the actuator system 114 to move the bond head 101. In various embodiments, the actuator system 114 may be configured to translate the bond head 101 vertically and/or horizontally. In some embodiments, the system controller 113 may also control the operation of the vacuum source 110 to selectively provide a suction force at each of the vacuum ports 108 in the nozzle plate 102. In some embodiments, the system controller 113 may also control the operation of the heat source 104 to selectively apply heat to the semiconductor IC die and the target substrate during a die bonding process.

Referring again to FIG. 1, the die bonding tool 100 may further include an internal chamber 105 and a moveable component 107 located at least partially within the internal chamber 105. The internal chamber 105 may be open at one end of the internal chamber 105, where the opening 115 to the internal chamber 105 may be substantially co-planar with the lower surface 103 of the nozzle plate 102. The moveable component 107 may be movable within the internal chamber 105 along a vertical direction (i.e., along a direction perpendicular to the planar lower surface 103 of the nozzle plate 102). At least one retaining member 106 may prevent the moveable component 107 from moving completely outside of the internal chamber 105. The at least one retaining member 106 may include, for example, a lip, a beveled surface, a flange, a gasket, or similar feature(s) located around the periphery of the internal chamber 105. The at least one retaining member 106 may define the width w of the opening 115 to the internal chamber 105. In various embodiments, a maximum width dimension d₃ of the moveable component 107 may be greater than the width w of the opening 115 to the internal chamber 105 defined by the at least one retaining member 106. Accordingly, the moveable component 107 may be prevented from completely exiting the internal chamber 105.

Referring again to FIG. 1, the lower surface 103 of the nozzle plate 102 may have a width dimension, d₁, along a first horizontal direction hd1. In some embodiments, the width dimension d₁ of the lower surface 103 of the nozzle plate 102 may be at least about 2 cm, although it will be understood that a nozzle plate 102 having a lower surface 103 with a width dimension d₁ of greater or smaller than 2 cm may also be utilized. The internal chamber 105 may be located in a central region of the nozzle plate 102. In some embodiments, a central axis of the internal chamber 105 may correspond to the geometric center of the nozzle plate 102. The internal chamber 105 may have a width dimension, d₂, along the first horizontal direction hd1 that is greater than the width w of the opening 115 to the internal chamber 105 defined by the at least one retaining member 106, and less than the width dimension, d₁, of the lower surface 103 of the nozzle plate 102. In some embodiments, d₂ may be less than or equal to half of d₁ (i.e., ≤1/2 of d₁). The maximum width dimension, d₃, of the moveable component 107 may be less than the width dimension, d₂, of the internal chamber 105. Thus, the moveable component 107 may be free to move up and down within the internal chamber 105 while being retained within the internal chamber 105 by the at least one retaining member 106. The nozzle plate 102, the internal chamber 105 and the moveable component 107 may have any suitable horizontal cross-section shape, such as a polygonal shape (e.g., rectangular, triangular), a circular shape, an elliptical shape, or an irregular shape.

In various embodiments, moveable component 107 may have a width dimension that narrows or tapers towards a lower surface of the lower component 107 such that a portion of the moveable component 107 may extend through the opening 115 to the internal chamber 105 defined by the at least one retaining member 106 and protrude below the plane of the lower surface 103 of the nozzle plate 102. In the embodiment of FIG. 1, the moveable component 107 includes a round outer surface having a width that tapers towards the lower surface of the moveable component 107. In other embodiments, the moveable component 107 may have an angled or stepped outer surface with a width that decreases toward the lower surface of the moveable component. In various embodiments, the lower surface of the moveable component 107 may protrude below the plane of the lower surface 103 of the nozzle plate 102 by a maximum protrusion distance, d₄. In some embodiments, the maximum protrusion distance d₄ may be at least about 0.1 μm. In some embodiments, the maximum protrusion distance d₄ of the moveable component 107 may be less than or equal to half of the maximum width dimension, d₃, of the moveable component 107 (i.e., d₄≤1/2 of the maximum width dimension, d₃, of the moveable component 107).

Referring again to FIG. 1, a fluid conduit 111 may be coupled the internal chamber 105 of the bond head 101 to a fluid source 112. The fluid source 112 may be configured to selectively provide a fluid to the internal chamber 105 via the fluid conduit 111 as schematically illustrated by arrow 116. In some embodiments, the fluid provided to the internal chamber may be a gas, such as air, H₂, O₂, N₂, Ar, and the like, including combinations thereof. In various embodiments, the fluid source 112 may be configured to control a flow rate of the fluid into the internal chamber 105. The fluid source 112 may include, for example, a variable speed blower or fan that may be used to control the flow rate of fluid into the internal chamber 105. Alternatively or in addition, the fluid source 112 may include one or more valves that may be used to control the flow rate of fluid into the internal chamber 105 (e.g., from a fluid storage container). In various embodiments, the fluid source 112 may be operatively coupled to the system controller 113 such that the system controller 113 may control the flow rate of fluid from the fluid source 112 to the internal chamber 105 of the bond head 101.

In various embodiments, the fluid flow into the internal chamber 105 of the bond head 101 may bias the movable component 107 against the at least one retaining member 106 such that the lower surface of the movable component 107 may protrude below the plane of the lower surface 103 of the nozzle plate 102 by the maximum protrusion distance, d₄, as shown in FIG. 1.

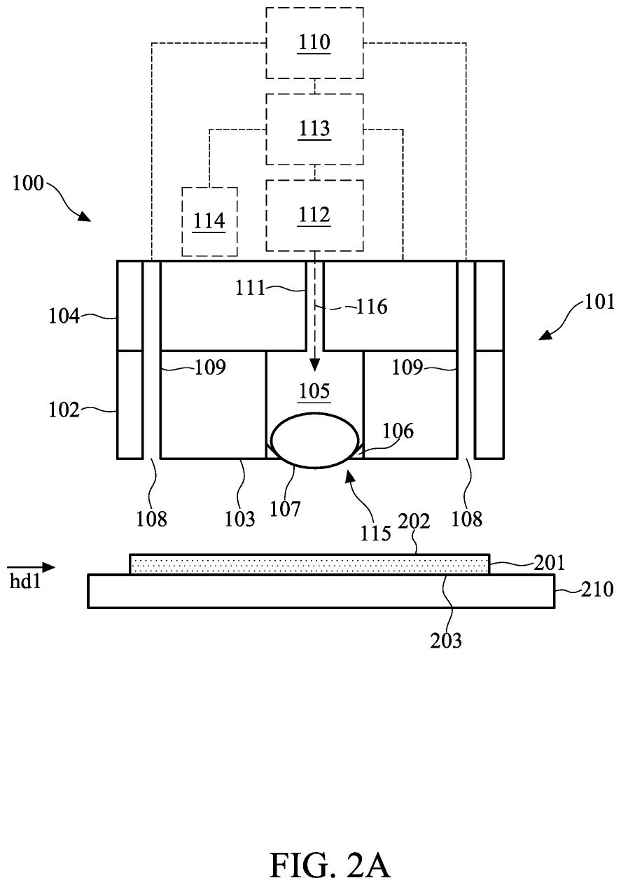

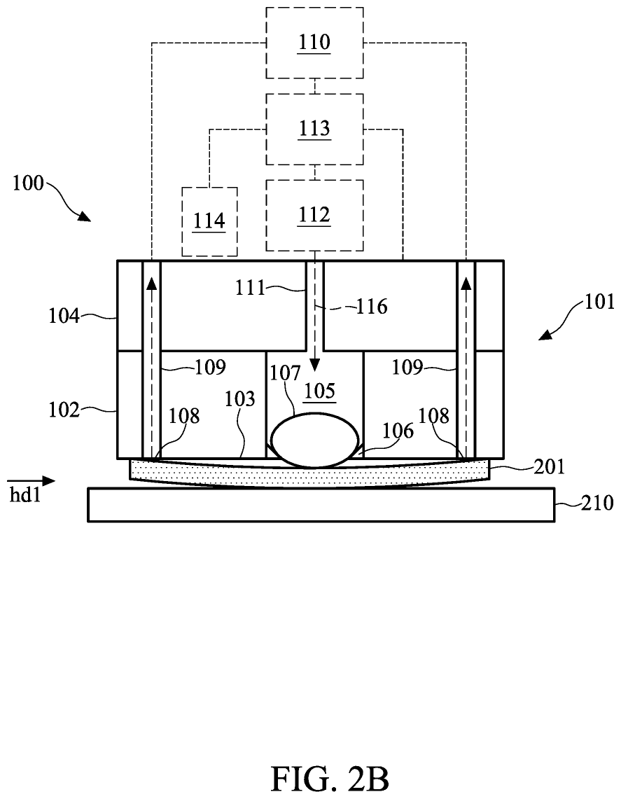

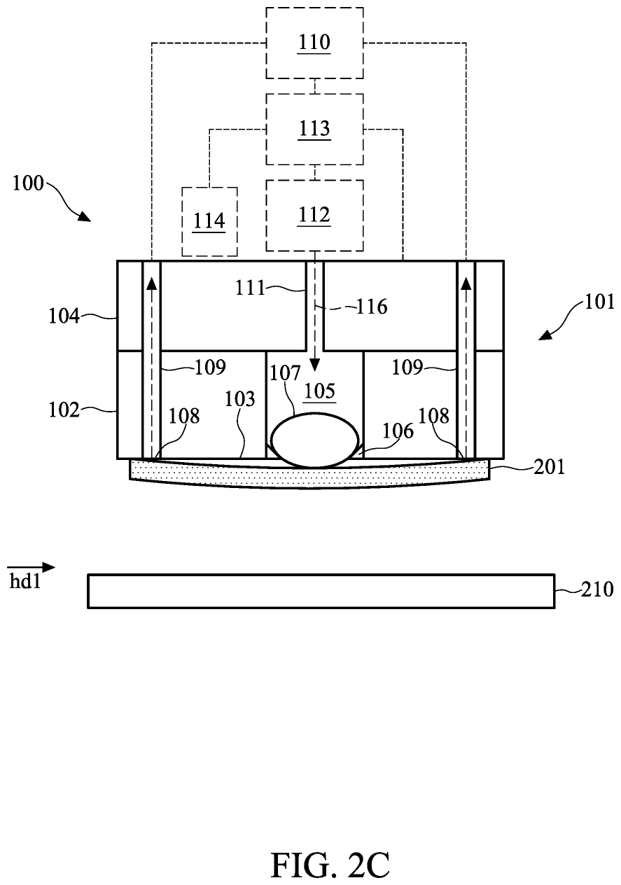

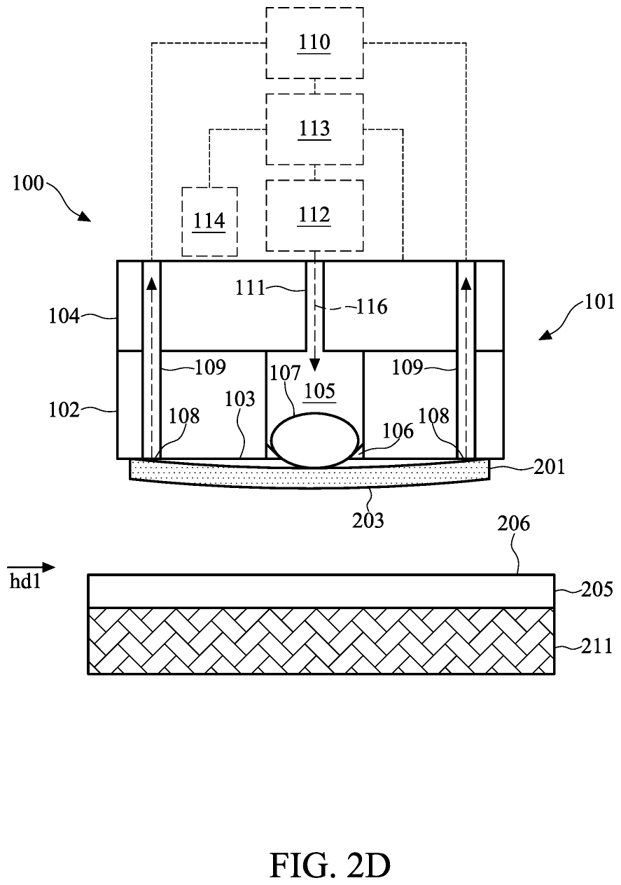

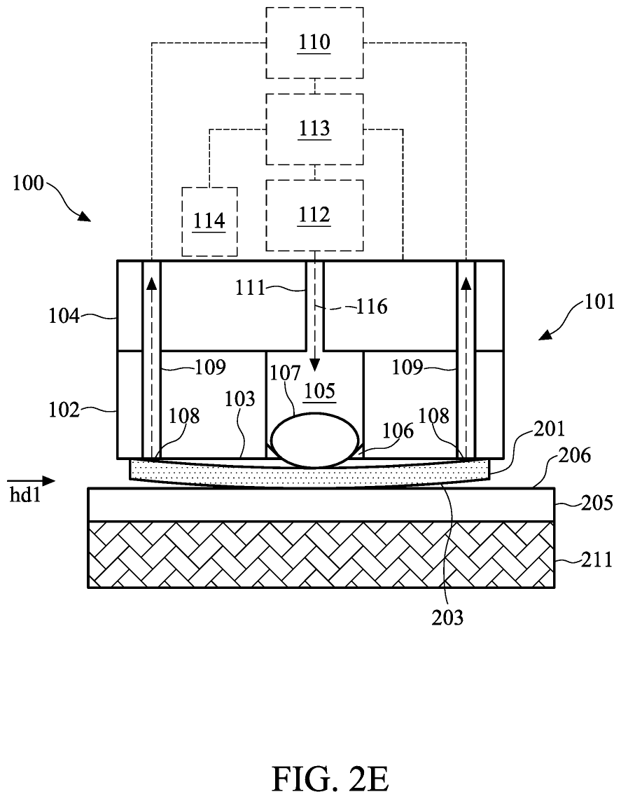

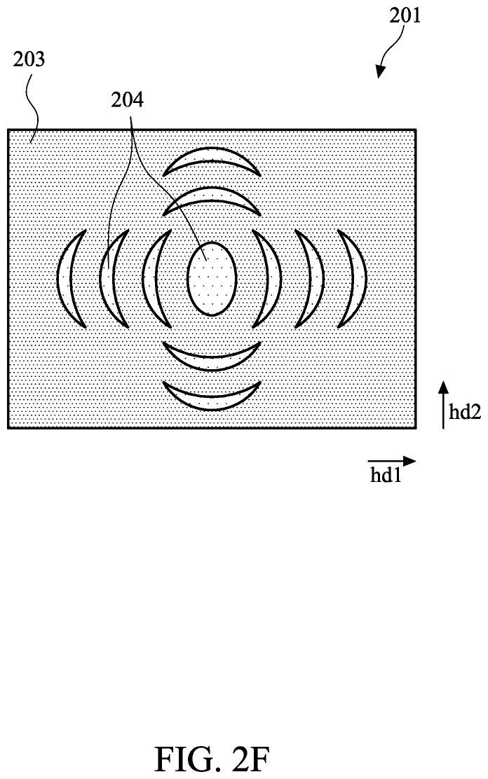

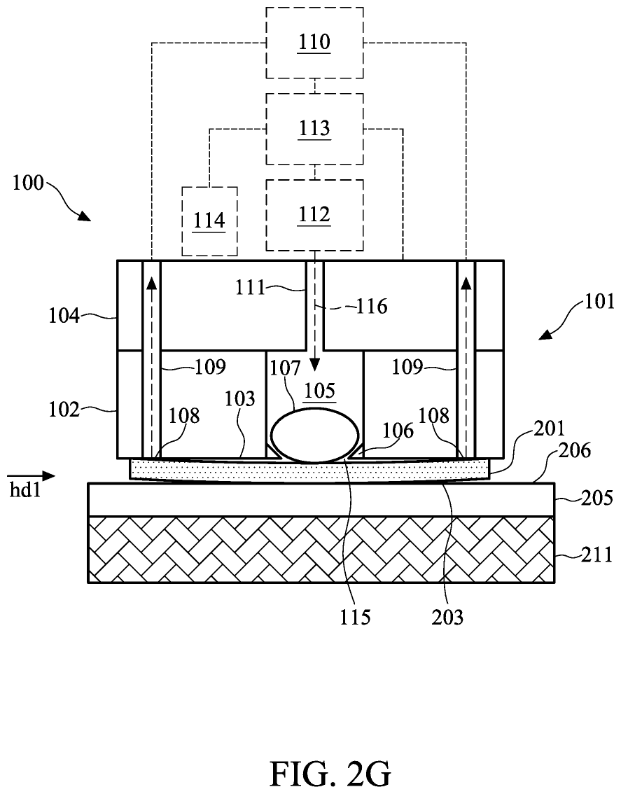

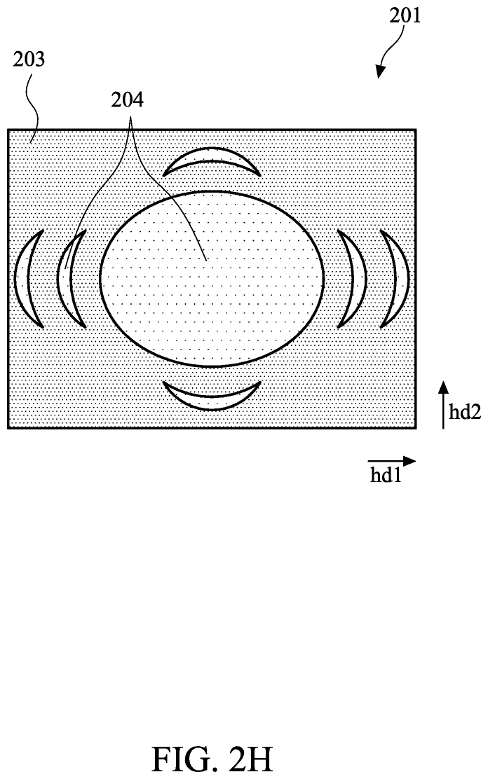

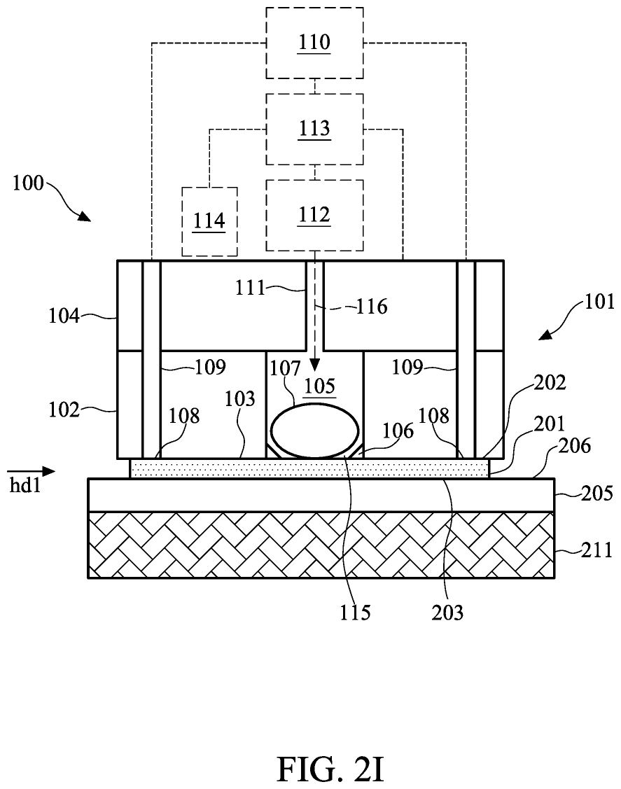

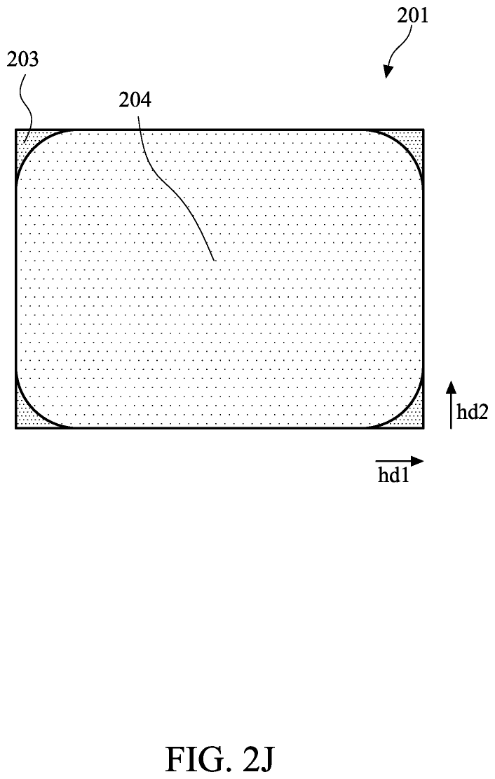

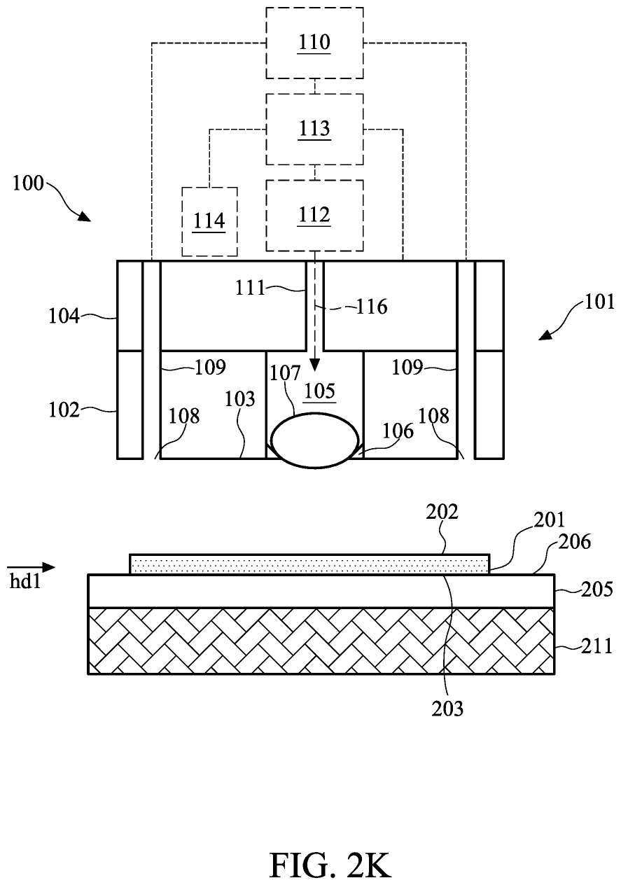

FIGS. 2A-2L illustrate a process of bonding a semiconductor IC die 201 to a target substrate 205 using a die bonding tool 100 according to various embodiments of the present disclosure. FIG. 2A illustrates the bond head 101 of the die bonding tool 100 aligned over the upper surface 202 of the semiconductor IC die 201 according to an embodiment of the present disclosure. The semiconductor IC die 201 may include a semiconductor material, such as silicon, having a number of circuit components and elements formed on and/or within the semiconductor material. Semiconductor IC dies 201 are typically fabricated by sequentially depositing insulating or dielectric layers, conductive layers, and semiconductive layers of material over a semiconductor substrate, patterning the various material layers using lithography to form integrated circuits, and separating individual dies from the wafer such as by sawing between the integrated circuits along scribe lines. In some embodiments, the semiconductor IC die 201 may be a system-on-chip (SoC) die. An SoC die may include, for example, an application processor die, a central processing unit die, and/or a graphic processing unit die. In some embodiments, the semiconductor IC die 201 may be a memory die. A memory die may include, for example, a dynamic random access memory (DRAM) die, and/or a high bandwidth memory (HBM) die. Other suitable semiconductor IC dies 201, such as an application-specific integrated circuit (ASIC) die, an analog die, a sensor die, a wireless and radio frequency die, a voltage regulator die, and the like, are within the contemplated scope of disclosure.

In some embodiments, the semiconductor IC die 201 may have a width dimension along the first horizontal direction hd1 that may be equal to or less than the width dimension, d₁, of the nozzle plate 102 of the bond head 101. In some embodiments, the width dimension of the semiconductor IC die 201 may be at least about 1.5 cm. The semiconductor IC die 201 may be located on a suitable support element 210, which may be, for example, a carrier substrate, a flexible support, such as a dicing tape supported by a tape frame, or a separate die handling tool, such a flip tool.

FIG. 2B is a vertical cross-section view of the die bonding tool 100 illustrating the bond head 101 contacting the upper surface 202 of the semiconductor IC die 201 according to various embodiments of the present disclosure. Referring to FIG. 2B, the bond head 101 may be brought into contact with the semiconductor IC die 201. In some embodiments, the system controller 113 may control the actuator system 114 to move the bond head 101 vertically downward to bring the bond head 101 into contact with the upper surface 202 of the semiconductor IC die 201. Alternatively, or in addition, the semiconductor IC die 201 may be moved vertically upwards using an ejector apparatus or another die handling tool to bring the upper surface 202 of the semiconductor IC die 201 into contact with the bond head 101. Fluid from the fluid source 112 flowing into the internal chamber 105 of the bond head 101 may push the movable component 107 against the at least one retaining member 106 such that the lower surface of the moveable component 107 may protrude below the plane of the lower surface 103 of the nozzle plate 102. In some embodiments, the lower surface of the movable component 107 may protrude below the plane of the lower surface 103 of the nozzle plate 102 by the maximum protrusion distance, d₄.

In various embodiments, the initial contact between the bond head 101 and the semiconductor IC die 201 may occur between the lower surface of the moveable component 107 and the upper surface 202 of the semiconductor IC die 201 in a central region of the semiconductor IC die 201. The suction force from each of the ports 108 in the nozzle plate 102 of the bond head 101 may pull the portions of the semiconductor IC die 201 underlying the ports 108 upwards towards the lower surface 103 of the nozzle plate 102. Thus, bond head 101 may impart a concave shape to the semiconductor IC die 201 that is secured to the bond head 101, where the lower surface 203 of the semiconductor IC die 201 may include a central region underlying the moveable component 107 that bulges downward relative to peripheral regions of the semiconductor IC die 201 that are pulled upwards towards the lower surface 103 of the nozzle plate 102 by the suction force of the ports 108 in the nozzle plate 102. The fluid pressure within the internal chamber 105 of the bond head 101 may be sufficient to maintain the lower surface of the movable component 107 protruding below the lower surface 103 of the nozzle plate 102.

FIG. 2C is a vertical cross-section view of the die bonding tool 100 illustrating the semiconductor IC die 201 secured to the bond head 101 according to various embodiments of the present disclosure. Referring to FIG. 2C, the suction force from the ports 108 in the lower surface 103 of the nozzle plate 102 may be sufficient to temporarily secure the semiconductor IC die 201 to the bond head 101. The semiconductor IC die 201 may be removed from the support element 210, such as by moving the bond head 101 and the semiconductor IC die 201 vertically upward away from the support element 210, and/or by moving the support element 210 away from the semiconductor IC die 201 that is temporarily secured to the bond head 101. The fluid pressure in the internal chamber 105 of the bond head 101 may be sufficient to maintain the lower surface of the movable component 107 protruding below the lower surface 103 of the nozzle plate. Thus, the lower surface 203 of the semiconductor die 201 may maintain the concave shape described above with respect to FIG. 2B.

FIG. 2D is a vertical cross-section view of the die bonding tool 100 illustrating the bond head 101 and the semiconductor IC die 201 attached thereto aligned over the upper surface 206 of a target substrate 205 according to an embodiment of the present disclosure. Referring to FIG. 2D, the actuator system 114 may move the bond head 101 along one or more horizontal directions to align the semiconductor IC die 201 over a portion of a target substrate 205 to which the semiconductor IC die 201 is to be bonded. The target substrate 205 may be located on a lower support member 211, such as a wafer chuck. In some embodiments, the target substrate 205 may be a semiconductor material substrate (i.e., a semiconductor wafer or semiconductor die). The semiconductor material substrate may have one or more integrated circuits formed on or in the substrate 205. Other suitable target substrates 205, such as glass, ceramic and/or organic material substrates, are within the contemplated scope of disclosure.

In various embodiments, the semiconductor IC die 201 may have bonding features (not shown in FIG. 2D) on the lower surface 203 of the semiconductor IC die 201. The target substrate 205 may have corresponding bonding features (not shown in FIG. 2D) on the upper surface 206 of the target substrate 205. In some embodiments, the bonding features may include bonding layers over the lower surface 203 of the semiconductor IC die 201 and bonding layers over the upper surface 206 of the target substrate 205, respectively, that may enable the semiconductor IC die 201 to be bonded to the target substrate 205 using a direct bonding technique, such as a metal-to-metal (M-M) and dielectric-to-dielectric (D-D) bonding technique. Each of the bonding layers may include plurality of bonding pads composed of a metallic material (e.g., copper) embedded in a dielectric material matrix. In various embodiments, the bonding layer(s) of the semiconductor IC die 201 and/or the target substrate 205 may optionally be pre-treated to promote surface activation (e.g., using a plasma treatment process). It will be understood that other types of bonding features, such as metal bumps, pillars, bonding pads and/or solder material portions), may be located on the lower surface 203 of the semiconductor IC die 201 and/or the upper surface 206 of the target substrate 205 in various embodiments. Other bonding techniques are within the contemplated scope of disclosure.

The fluid pressure in the internal chamber 105 of the bond head 101 may be sufficient to maintain the lower surface of the movable component 107 protruding below the lower surface 103 of the nozzle plate. Thus, the lower surface 203 of the semiconductor die 201 may maintain the concave shape described above with respect to FIG. 2B.

FIG. 2E is a vertical cross-section view of the die bonding tool 100 illustrating the bond head 101 and the semiconductor IC die 201 attached thereto moved vertically downward towards the upper surface 206 of the target substrate 205 according to an embodiment of the present disclosure. Referring to FIG. 2E, the actuator system 114 may cause the bond head 101 and the semiconductor IC die 201 to move vertically downward to bring the lower surface 203 of the semiconductor IC die 201 into contact with the upper surface 206 of the target substrate 205. Alternatively, the lower support member 211 (wafer chuck) supporting the target substrate may be moved upward to contact the semiconductor IC die 201 that is temporarily secured to the bond head 101. The fluid pressure in the internal chamber 105 of the bond head 101 may be sufficient to maintain the lower surface of the movable component 107 protruding below the lower surface 103 of the nozzle plate such that the lower surface 203 of the semiconductor die 201 may have a concave shape as described above with respect to FIG. 2B. Accordingly, the initial contact between the lower surface 203 of the semiconductor IC die 201 and the upper surface 206 of the target substrate 205 may occur in the central region of the semiconductor IC die 201. In various embodiments, by controlling the deformation of the semiconductor IC die 201 as shown in FIG. 2E, the location of the initial contact between the lower surface 203 of the semiconductor IC die 201 and the upper surface 206 of the target substrate 205 may be controlled. This may improve the bonding of the semiconductor IC die 201 to the target substrate 205 and inhibit the formation of air pockets or bubbles between the semiconductor IC die 201 and the target substrate 205.

FIG. 2F is a bottom-up view of the semiconductor IC die 201 schematically illustrating the bonding wave 204 produced during a process of bonding the lower surface 203 of the semiconductor IC die 201 to the upper surface 206 of the target substrate 205. Referring to FIG. 2F, in a direct bonding process, such as a metal-to-metal (M-M) and dielectric-to-dielectric (D-D) bonding process, bringing the semiconductor IC die 201 into contact with the target substrate 205 may result in a pre-bonding process in which chemical bonds (e.g., hydrogen bridge bonds) may form between the bonding layer on the lower surface 203 of the semiconductor IC die 201 and the corresponding bonding layer on the upper surface 206 of the target substrate 205. The front along which these chemical bonds form may be referred to as the “bonding wave.” The shape and propagation of the bonding wave may be influenced by a variety of factors, including the mechanical strain and/or deformation of the semiconductor IC die 201 and/or the target substrate 205. In various embodiments of the present disclosure, by utilizing a bond head 101 that controls the shape and deformation of the semiconductor IC die 201 during the bonding process, improved control over the formation of the bonding wave may be achieved. In particular, the bonding wave may form initially in the central region of the semiconductor IC die 201 that makes initial contact with the target substrate 205 and may propagate radially outwards towards the edges of the semiconductor IC die 201. FIG. 2F schematically illustrates the bonding wave 204 propagating from the central region of the semiconductor IC die 201 towards the edges of the semiconductor IC die 201 during a direct bonding process.

FIG. 2G is a vertical cross-section view of the die bonding tool 100 illustrating the bond head 101 and the semiconductor IC die 201 attached thereto moved further towards the upper surface 206 of the target substrate 205 according to an embodiment of the present disclosure. In alternative embodiments, the lower support member 211 (wafer chuck) may be moved upward toward the semiconductor IC die being temporarily secured to the bond head 101. Referring to FIG. 2G, the actuator system 114 may cause the bond head 101 and the semiconductor IC die 201 to continue to move vertically downward to bring more of the lower surface 203 of the semiconductor IC die 201 into contact with the upper surface 206 of the target substrate 205. In various embodiments, as the bond head 101 and the semiconductor IC die 201 continue to move towards the upper surface 206 of the target substrate 205, the movable component 107 may be partially retracted into the internal chamber 105 of the bond head 101 such that the distance by which the lower surface of the moveable component 107 protrudes below the lower surface 103 of the nozzle plate 102 may be less than the maximum protrusion distance, d₄. In some embodiments, the flow rate of the fluid 116 from the fluid source 112 through the fluid conduit 111 into the internal chamber 105 may be reduced, or the fluid flow may be turned off completely, to facilitate the partial retraction of the movable component 107 into the internal chamber 105. The partial retraction of the moveable component 107 into the internal chamber 105 may cause the concave “bulge” in the central region of the lower surface 203 of the semiconductor IC die 201 to diminish and the semiconductor IC die 201 to flatten out such that the contact area between the lower surface 203 of the semiconductor IC die 201 and the upper surface 206 of the target substrate 205 may be gradually increased.

FIG. 2H is a bottom-up view of the semiconductor IC die 201 schematically illustrating the propagation of the bonding wave 204 during the subsequent stage of the bonding process according to various embodiments of the present disclosure. Referring to FIG. 2H, as the contact area between the lower surface 203 of the semiconductor IC die 201 and the upper surface 206 of the target substrate 205 is gradually increased, the bonding wave 204 may continue to propagate outwards from the central region of the semiconductor IC die 201 towards the edges of the semiconductor IC die 201 as shown in FIG. 2H. In various embodiments, the gradual increase in the contact area between the semiconductor IC die 201 and the target substrate 205 may enable a controlled propagation of the bonding wave radially outward from the center to the edges of the semiconductor IC die 201 without interruption by trapped air pockets or bubbles.

FIG. 2I is a vertical cross-section view of the die bonding tool 100 illustrating the bond head 101 moved further towards the upper surface 206 of the target substrate 205 to bring the entire lower surface 203 of the semiconductor IC die 201 into contact with the upper surface 206 of the target substrate 205 according to an embodiment of the present disclosure. Referring to FIG. 2I, as the bond head 101 moves closer to the upper surface 206 of the target substrate 205, the moveable component 107 may continue to retract into the internal chamber 105. Accordingly, the concave “bulge” in the lower surface 203 of the semiconductor IC die 201 may continue to diminish and the semiconductor IC die 201 may continue to flatten out and the contact area between the lower surface 203 of the semiconductor IC die 201 and the upper surface 206 of the target substrate 205 may increase until the entire lower surface 203 of the target substrate 203 contacts the upper surface 206 of the target substrate 205. As shown in FIG. 2I, the moveable component 107 may be retracted into the internal chamber 105 such that the lower surface of the moveable component 107 does not protrude below the plane of the lower surface 103 of the nozzle plate 102.

FIG. 2J is a bottom-up view of the semiconductor IC die 201 schematically illustrating the propagation of the bonding wave 204 during a subsequent stage of the bonding process according to various embodiments of the present disclosure. Referring to FIG. 2J, the bonding wave 204 may continue to propagate outwards to the edges of the semiconductor IC die 201 as the contact area between the semiconductor IC die 201 and the target substrate 205 increases. FIG. 2J illustrates the bonding wave 204 having reached almost the entire area of the semiconductor IC die 201 except for the four corner regions of the semiconductor IC die 201. In various embodiments, the bonding wave 204 may eventually propagate over the entire surface of the semiconductor IC die 201.

FIG. 2K is a vertical cross-section view of the die bonding tool 100 following a bonding process that bonds the semiconductor IC die 201 to the target substrate 205 according to an embodiment of the present disclosure. In some embodiments, the semiconductor IC die 201 may be bonded to the target substrate 205 using a direct bonding technique, such as a metal-to-metal (M-M) and dielectric-to-dielectric (D-D) bonding technique. The bond head 101 may be used to apply a compressive force to the upper surface 202 of the semiconductor IC die 201 during the bonding process. In some embodiments, the flow rate of fluid 116 into the internal chamber 105 may be increased during the bonding process to bias the lower surface of the movable component 107 against the upper surface 202 of the semiconductor IC die 201. In some embodiments, the semiconductor IC die 201 and the target substrate 205 may be subjected to an elevated temperature, such as a temperature between about 150° C. and about 450° C., during the bonding process. In some embodiments, the elevated temperature may be provided by the above-described heat source 104 on the die bonding tool 100. The compressive force and heat provided by the die bonding tool 100 may result in the formation of a strong bond between the bonding layer on the lower surface 203 of the semiconductor IC die 201 and the corresponding bonding layer on the upper surface 206 of the target substrate 205.

In various embodiments, the die bonding tool 100 may release the semiconductor IC die 201 from the lower surface 103 of the nozzle plate 102 either prior to, during, or following the bonding process. The die bonding tool 100 may release the semiconductor die 201 from the lower surface 103 of the nozzle plate 102 by turning off/disconnecting the vacuum source 110 and/or by providing an ambient or positive pressure within the fluid conduits 109, thereby releasing the suction force at the ports 108 in the nozzle plate 102. Following the release of the semiconductor IC die 201 from the lower surface 103 of the nozzle plate 102, the system controller 113 may cause the actuator system 114 to move the bond head 101 vertically upwards and away from the semiconductor IC die 201, as shown in FIG. 2K.

It will be understood that other bonding processes may be used to bond the semiconductor IC die 201 to the target substrate 205. For example, a thermocompression bonding (TCB) process may be utilized to bond metallic structures (e.g., metal bumps, pillars and/or bonding pads) on the lower surface of the semiconductor IC die 201 to corresponding metallic structures (e.g., metal bumps, pillars and/or bonding pads) on the upper surface of the target substrate 205. The tool head 101 of the die bonding tool 100 may apply a compressive force to the semiconductor IC die 201 while the semiconductor IC die 201 and the target substrate 205 are heated. In some embodiments, the semiconductor IC die 201 and the target substrate 205 may be heated by an above-described heat source 104 on the die bonding tool 100. With the applied pressure and the elevated temperature, surface portions of the metallic structures of the semiconductor IC die 201 and the metallic structures of the target substrate 205 may inter-diffuse, so that bonds may be formed therebetween. In some embodiments, the bonding between the semiconductor IC die 201 and the target substrate 205 may be performed without the use of solder material. In other embodiments, a solder material may be used to bond bonding structures of the semiconductor IC die 201 to corresponding bonding structures of the target substrate 205.

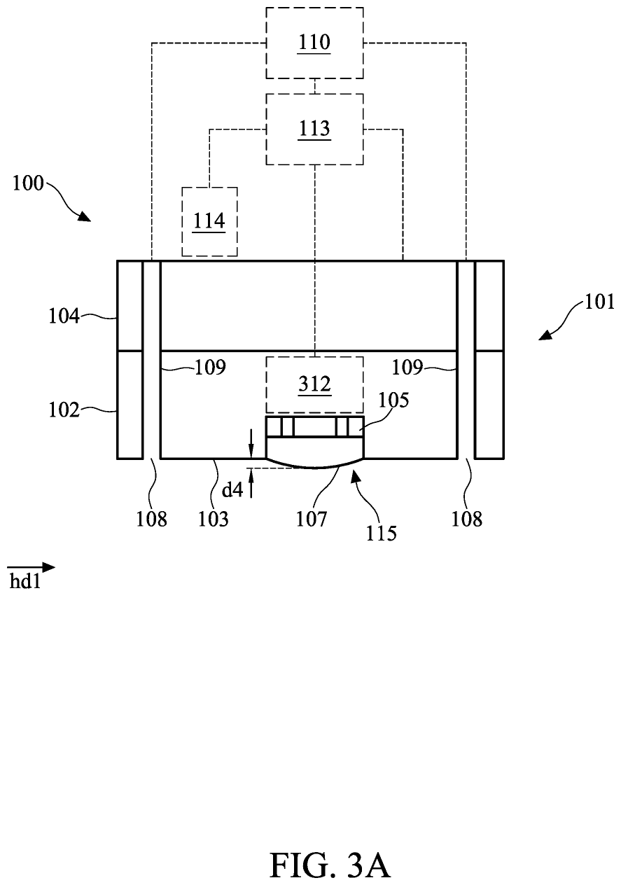

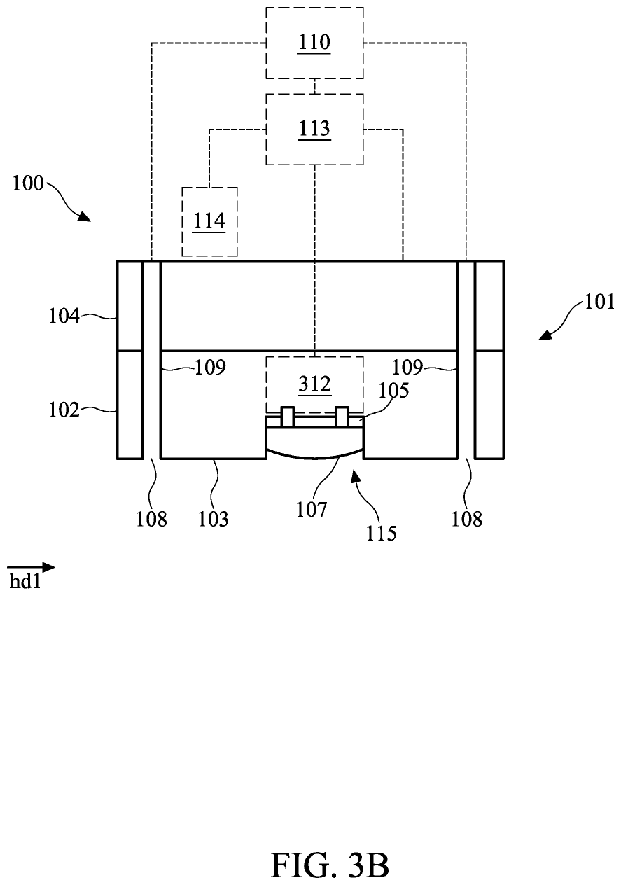

FIGS. 3A and 3B are vertical cross-section view of a die bonding tool 100 including a moveable component 107 according to another embodiment of the present disclosure. The die bonding tool 100 shown in FIGS. 3A and 3B may be similar to the die bonding tool 100 described above with reference to FIGS. 1-2K. Thus, repeated discussion of like elements is omitted for brevity. The die bonding tool 100 in FIGS. 3A and 3B differs from the die bonding tool 100 of FIGS. 1-2K in that a motorized system 312 may drive the movement of the movable component 107 with respect to the internal chamber 105 of the bond head 101. In various embodiments, the motorized system 312 may include one or more motors, linear actuators, cams, sliders, linkages, plungers, and/or feedback sensors (e.g., encoders), etc., that may be configured to controllably move the moveable component 107 with respect to the internal chamber 105 of the bond head 101. The motorized system 312 may be controlled by the system controller 113. The motorized system 312 may be configured to move the movable component 107 between a position as shown in FIG. 3A, in which the lower surface of the moveable component 107 protrudes below the plane of the lower surface 103 of the nozzle plate 102 by a maximum protrusion distance, d₄, and a position as shown in FIG. 3B, in which the lower surface of the moveable component 107 does not protrude below the plane of the lower surface 103 of the nozzle plate 102. The die bonding tool 100 as shown in FIGS. 3A and 3B may be used to bond a semiconductor IC die 201 that is temporarily adhered to the bond head 101 to a target substrate 205 as illustrated and described above with reference to FIGS. 2A-2K.

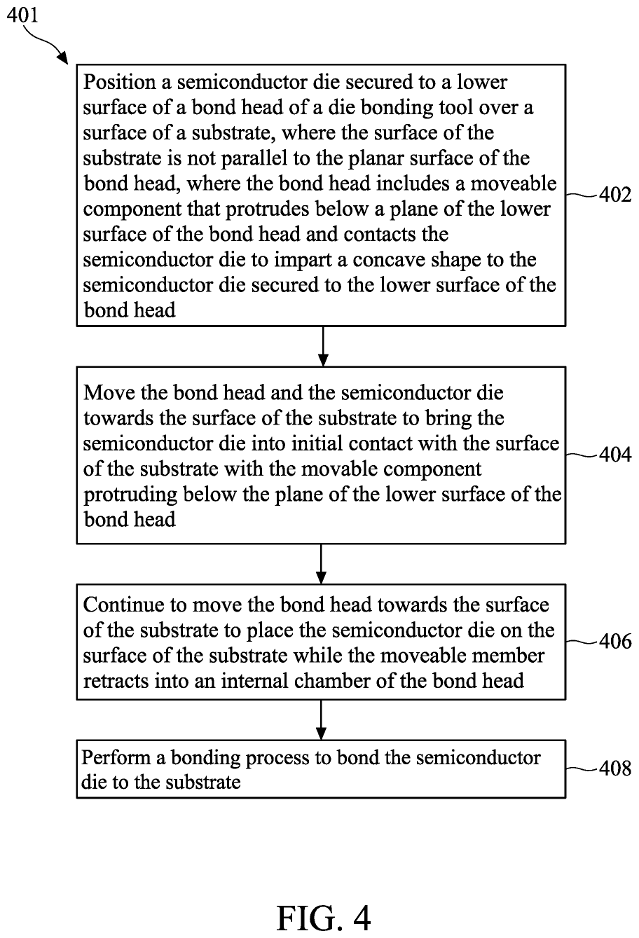

FIG. 4 is a flowchart illustrating a method 401 of bonding a semiconductor IC die 201 to a target substrate 205 using a die bonding tool 100 according to an embodiment of the present disclosure. Referring to FIGS. 2A-2D and 4, in step 402 of method 401, a semiconductor die 201 secured to a lower surface 103 a bond head 101 of the die bonding tool 100 may be positioned over a surface 206 of a substrate 205, where the bond head 101 includes a moveable component 107 that protrudes below a plane of the lower surface 103 of the bond head 101 and contacts the semiconductor die 201 to impart a concave shape to the semiconductor die 201 secured to the lower surface 103 of the bond head 101.

Referring to FIGS. 2E, 2F and 4, in step 404 of method 401, the bond head 101 and the semiconductor IC die 201 may be moved toward one another such that the upper surface 206 of the substrate 205 may be brought into initial contact with the lower surface 203 of the semiconductor die 201 with the movable member 107 protruding below the plane of the lower surface 103 of the bond head 101. Referring to FIGS. 2G, 2H, 2I, 2J and 4, in step 406 of method 401, the bond head 101 and the semiconductor die 105 may continue to move toward one another such that the surface 206 of the substrate 205 contacts the semiconductor die 201 while the moveable member 107 retracts into an internal chamber 105 of the bond head 101. Referring to FIGS. 2I, 2J, 2K and 4, in step 408 of method 401, a bonding process may be performed to bond the semiconductor die 201 to the surface 206 of the substrate 205.

Referring to all drawings and according to various embodiments of the present disclosure, a die bonding tool 100 includes a bond head 101 configured to secure a semiconductor die 201 temporarily to a lower surface 103 of the bond head 101, the bond head 101 including a moveable component 107 located at least partially within an internal chamber 105 of the bond head 101, where the moveable component 107 is moveable with respect to the internal chamber 105 between a first position in which a lower surface of the moveable component 107 protrudes below the lower surface 103 of the bond head 101 and a second position in which the lower surface of the moveable component 107 does not protrude below the lower surface 103 of the bond head 101, an actuator system 114 configured to move the bond head 101 and the semiconductor die 201 temporarily secured thereto towards an upper surface 206 of a target substrate 205.

In one embodiment, the lower surface 103 of the bond head 101 includes a lower surface 103 of a nozzle plate 102 having at least one port 108 therein, and the die bonding tool 100 further includes a vacuum source 110 fluidly coupled to the at least one port 108 in the nozzle plate 102 and configured to selectively generate a suction force at the at least one port 108 in the nozzle plate 102 to secure the semiconductor die 201 temporarily against the lower surface 103 of the nozzle plate 102.

In another embodiment, the internal chamber 105 is located in a central region of the nozzle plate 102 and includes an opening 115 that is coplanar with the lower surface 103 of the nozzle plate 102.

In another embodiment, a width dimension d₂ of the internal chamber 105 is equal to or less than half of a width dimension d₁ of the lower surface 103 of the nozzle plate 102.

In another embodiment, the lower surface of the moveable component 107 is configured to protrude below the plane of the lower surface 103 of the nozzle plate 102 by a maximum protrusion distance d₄ of at least 0.1 μm.

In another embodiment, the die bonding tool 100 further includes a fluid source 112 configured to selectively provide a fluid to the internal chamber 105 of the bond head 101 to control a position of the moveable component 107 with respect to the internal chamber 105.

In another embodiment, the die bonding tool 100 further includes at least one retaining member 106 located around a periphery of the internal chamber 105 of the bond head 101 and defining a width w of an opening 115 to the internal chamber 105.

In another embodiment, a maximum width d₃ of the moveable component 107 is greater than the width w of the opening 115 to the internal chamber 105 defined by the at least one retaining member 106.

In another embodiment, a lower portion of the moveable component 107 includes a curved, angled or stepped outer surface to enable the lower portion of the moveable component 107 to protrude from the internal chamber 105 below the plane of the lower surface 103 of the nozzle plate 102.

In another embodiment, a maximum distance d₄ by which the moveable component 107 is able to protrude below the plane of the lower surface 103 of the nozzle plate 102 is ≤1/2 the maximum width d₃ of the moveable component 107.

In another embodiment, the die bonding tool 100 further includes a motorized system 312 that is configured to drive the movement of the movable component 107 with respect to the internal chamber 105 of the bond head 101.

Another embodiment is drawn to a die bonding tool 100 including a bond head 101 configured to secure a semiconductor die 201 temporarily against a lower surface 103 of the bond head 101, the bond head 101 including a moveable component 107 that is moveable with respect to the lower surface 103 of the bond head 101, and a system controller 113 operatively coupled to the bond head 101 and configured to control a movement of the bond head 101 and the semiconductor die 201 secured thereto with respect to a target substrate 205, and control a position of the moveable component 107 with respect to the lower surface 103 of the bond head 101.

In one embodiment, the die bonding system 100 further includes an actuator system 114 coupled to the bond head 101, where the system controller 113 controls the actuator system 114 to move the bond head 101 with respect to the target substrate 205, and a vacuum source 110 fluidly coupled to at least one port 108 in the lower surface 103 of the bond head 101, where the system controller 113 controls the vacuum source 110 to selectively provide a suction force at the at least one port 108 to secure the semiconductor die 201 against the lower surface 103 of the bond head 101.

In another embodiment, the die bonding tool 100 further includes a fluid source 112 in fluid communication with the moveable component 107, where the system controller 113 controls a flow of fluid from the fluid source 112 to the moveable component 107 to control a position of the moveable component 107 with respect to the lower surface 103 of the bond head 101.

In another embodiment, the die bonding tool 100 further includes a motorized system 312, where the system controller 113 controls the motorized system 312 to drive the movement of the movable component 107 with respect to the lower surface 103 of the bond head 101.

In another embodiment, the die bonding tool 100 further includes a heat source 104, where the system controller 113 controls the heat source 104 to selectively heat the semiconductor die 201.

Another embodiment is drawn to a method of bonding a semiconductor die 201 to a substrate 205 that includes positioning the semiconductor die 201 secured to a lower surface 103 of a bond head 101 of the die bonding tool 100 over a surface 206 of the substrate 205, where the bond head 101 includes a moveable component 107 that protrudes below a plane of the lower surface 103 of the bond head 101 and contacts the semiconductor die 201 to impart a concave shape to the semiconductor die 201 secured to the lower surface 103 of the bond head 101, moving the bond head 101 and the semiconductor die 201 towards the surface 206 of the substrate 205 to bring the semiconductor die 201 into initial contact with the surface 206 of the substrate 205 with the moveable component 107 protruding below the plane of the lower surface 103 of the bond head 101, continuing to move the bond head 101 towards the surface 206 of the substrate 205 to place the semiconductor die 201 on the surface 206 of the substrate 205 while the moveable member 107 retracts into an internal chamber 105 of the bond head 101, and performing a bonding process to bond the semiconductor die 201 to the surface 206 of the substrate 205.

In one embodiment, placing the semiconductor die 201 on the surface 206 of the substrate 205 produces a bonding wave 204 that propagates from a central region of the semiconductor die 201 radially outwards towards peripheral edges of the semiconductor die 201.

In another embodiment, the method includes flowing a fluid into the internal chamber 105 of the bond head 101 to maintain the moveable component 107 protruding below the lower surface 103 of bond head 101 as the bond head 101 and the semiconductor die 201 move towards the surface 206 of the substrate 205 to bring the semiconductor die 201 into initial contact with the surface 206 of the substrate 205, and reducing a flow rate of the fluid flow into the internal chamber 105 of the bond head 101 following the initial contact between the semiconductor die 201 and the substrate 205 to enable the moveable component 107 to retract into the internal chamber 105 as the semiconductor die 201 is placed on the substrate 205.

In another embodiment, the method includes controlling a motorized system 312 coupled to the moveable component 107 to cause the moveable component 107 to retract into the internal chamber 105.

The various embodiments disclosed herein provide a die bonding tool 100 and methods for using the embodiment die bonding tool 100 that aligns a semiconductor IC die 201 with a target substrate 205. Various embodiments of the die bonding tool 100 may temporarily secure the semiconductor IC die 201 to a lower surface 103 of the bond head 101 using a suction force applied through one or more openings or ports in the lower surface of the bond head. Various embodiments of the die bonding tool 100 may temporarily secure the semiconductor IC die 201 to a lower surface 103 of the bond head 101 to provide a concave shape to the semiconductor IC die 201. In this manner, the various embodiment die bonding tools 100 may contact and bond the semiconductor IC die 201 to the target substrate 205 to prevent voids, air pockets or bubbles that may otherwise become trapped between the lower surface 203 of the semiconductor IC die 201 and the upper surface 206 of the target substrate 205 during the bonding process. Accordingly, following the bonding process, the existence of void areas between the interfacing surfaces of the semiconductor IC die and the target substrate may be mitigated against so as to improve device yields.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A die bonding tool, comprising:
a bond head configured to secure a semiconductor die temporarily to a lower surface of the bond head, the bond head comprising a moveable component located at least partially within an internal chamber of the bond head, wherein the moveable component is moveable with respect to the internal chamber between a first position in which a lower surface of the moveable component protrudes below the lower surface of the bond head and a second position in which the lower surface of the moveable component does not protrude below the lower surface of the bond head; and
an actuator system configured to move the bond head and the semiconductor die temporarily secured thereto towards an upper surface of a target substrate.

2. The die bonding tool of claim 1, wherein the lower surface of the bond head comprises a lower surface of a nozzle plate having at least one port therein, and the die bonding tool further comprises:
a vacuum source fluidly coupled to the at least one port in the nozzle plate and configured to selectively generate a suction force at the at least one port in the nozzle plate to secure the semiconductor die temporarily against the lower surface of the nozzle plate.

3. The die bonding tool of claim 2, wherein the internal chamber is located in a central region of the nozzle plate and comprises an opening that is coplanar with the lower surface of the nozzle plate.

4. The die bonding tool of claim 3, wherein a width dimension of the internal chamber is equal to or less than half of a width dimension of the lower surface of the nozzle plate.

5. The die bonding tool of claim 2, wherein the lower surface of the moveable component is configured to protrude below a plane of the lower surface of the nozzle plate by a maximum protrusion distance of at least 0.1 μm.

6. The die bonding tool of claim 2, further comprising:
a fluid source configured to selectively provide a fluid to the internal chamber of the bond head to control a position of the moveable component with respect to the internal chamber.

7. The die bonding tool of claim 6, further comprising:
at least one retaining member located around a periphery of the internal chamber of the bond head and defining a width of an opening to the internal chamber.

8. The die bonding tool of claim 7, wherein a maximum width of the moveable component is greater than the width of the opening to the internal chamber defined by the at least one retaining member.

9. The die bonding tool of claim 8, wherein a lower portion of the moveable component comprises a curved, angled or stepped outer surface to enable the lower portion of the moveable component to protrude from the internal chamber below a plane of the lower surface of the nozzle plate.

10. The die bonding tool of claim 9, wherein a maximum distance by which the moveable component is able to protrude below the plane of the lower surface of the nozzle plate is equal to or less than half of the maximum width of the moveable component.

11. The die bonding tool of claim 1, further comprising a motorized system that is configured to drive a movement of the movable component with respect to the internal chamber of the bond head.

12. A die bonding tool, comprising:
a bond head configured to secure a semiconductor die temporarily against a surface of the bond head, the bond head comprising a moveable component that is moveable with respect to the surface of the bond head; and
a system controller operatively coupled to the bond head and configured to:
control a movement of the bond head and a semiconductor die secured thereto with respect to a target substrate; and
control a position of the moveable component with respect to the surface of the bond head.

13. The die bonding tool of claim 12, further comprising:
an actuator system coupled to the bond head, wherein the system controller controls the actuator system to move the bond head with respect to the target substrate; and
a vacuum source fluidly coupled to at least one port in the surface of the bond head, wherein the system controller controls the vacuum source to selectively provide a suction force at the at least one port to secure the semiconductor die against the surface of the bond head.

14. The die bonding tool of claim 13, further comprising:
a fluid source in fluid communication with the moveable component, wherein the system controller controls a flow of fluid from the fluid source to the moveable component to control a position of the moveable component with respect to the surface of the bond head.

15. The die bonding tool of claim 13, further comprising:
a motorized system, wherein the system controller controls the motorized system to drive the movement of the movable component with respect to the surface of the bond head.

16. The die bonding tool of claim 13, further comprising:
a heat source, wherein the system controller controls the heat source to selectively heat the semiconductor die.

17. A method of bonding a semiconductor die to a substrate using a die bonding tool, comprising:
positioning the semiconductor die secured to a lower surface of a bond head of the die bonding tool over a surface of the substrate, wherein the bond head comprises a moveable component that protrudes below a plane of the lower surface of the bond head and contacts the semiconductor die to impart a concave shape to the semiconductor die secured to the lower surface of the bond head;
moving the bond head and the semiconductor die toward the surface of the substrate to bring the semiconductor die into initial contact with the surface of the substrate with the moveable component protruding below the plane of the lower surface of the bond head;
continuing to move the bond head towards the surface of the substrate to place the semiconductor die on the surface of the substrate while the moveable component retracts into an internal chamber of the bond head; and
performing a bonding process to bond the semiconductor die to the surface of the substrate.

18. The method of claim 17, wherein placing the semiconductor die on the surface of the substrate produces a bonding wave that propagates from a central region of the semiconductor die radially outwards towards peripheral edges of the semiconductor die.

19. The method of claim 17, further comprising flowing a fluid into the internal chamber of the bond head to maintain the moveable component protruding below the lower surface of bond head as the bond head and the semiconductor die move towards the surface of the substrate to bring the semiconductor die into initial contact with the surface of the substrate; and
reducing a flow rate of a fluid flow into the internal chamber of the bond head following the initial contact between the semiconductor die and the substrate to enable the moveable component to retract into the internal chamber as the semiconductor die is placed on the substrate.

20. The method of claim 17, further comprising controlling a motorized system coupled to the moveable component to cause the moveable component to retract into the internal chamber.
